(19) United States
(12) Patent Application Publication
(10) Pub. No.: US 2012/0319405 A1
(43) Pub. Date: Dec. 20, 2012

(54) DEEP OCEAN CURRENT POWER PLANT AND CONSTRUCTING PROCEDURE THEREOF

(75) Inventors: Falin Chen, Taipei (TW); Si-Chen Lee, Taipei (TW); Shyi-Min Lu, Taipei (TW)

(73) Assignee: NATIONAL TAIWAN UNIVERSITY, Taipei (TW)

(21) Appl. No.: 13/274,021

(22) Filed: Oct. 14, 2011

(30) Foreign Application Priority Data
Jun. 15, 2011 (TW) 100120817

(51) Int. Cl. F03B 13/10; H05K 13/00

(52) U.S. Cl. 290/52; 29/592.1

(57) ABSTRACT

A deep ocean current power plant comprises a current generator group, a floating midway platform, a generator anchorage system, a midway platform anchorage system, and at least one power transmission-and-distribution cable. The constructing procedure of the deep ocean current power plant comprises following steps of sea-cast anchoring and cable-numbering; platform assembling and undersea anchoring; current generator group anchoring; and testing and correcting a stability of whole structure.

### CROSS-REFERENCE TO RELATED APPLICATION

This non-provisional application claims priority under 35 U.S.C. §119(a) on Patent Application No. 100120817 filed in Taiwan R.O.C. on Jun. 15, 2011, the entire contents of which are hereby incorporated by reference.

### FIELD OF THE INVENTION

The present invention is a deep ocean current power plant and constructing procedure thereof. Specifically, the invention is used in ocean with depth of more than 40 meters, and it is able to convert kinetic energy generated from ocean current into electrical energy.

### BACKGROUND OF THE INVENTION

Currently, there is no precedent of building a deep ocean current power plant in the world, but there are many testing turbines designed for tidal power plants in shallow sea of which the depth is within 20 meters. For example, the company, Seagen & Seaflow based in UK, set up a single turbine of 300 kW named SeaFlow in Lynmouth, on the North Devon Coast of the United Kingdom on May 2003 (refer to Kuroshio power plant development plan. Renewable and Sustainable Energy Reviews 14 (2010) 2655-2668). In 2008, Strangford Lough of Northern Ireland successfully set up a dual turbine of 1.2 MW named SeaGen (refer to Kuroshio power plant development plan. Renewable and Sustainable Energy Reviews 14 (2010) 2655-2668). The generator which is running approximately 18-20 h/day has a link to the local power grid.

Recently, a demonstrative power plant with a power capacity of 20-25 kW located on the coast of British Columbia province in Canada, and the Retrofit Bridge Project located in Tacoma City, Wash. state in United States will set up Davis Hydro Turbines under the bridge (refer to Kuroshio power plant development plan. Renewable and Sustainable Energy Reviews 14 (2010) 2655-2668). The above projects are still categorized into tidal power plants in shallow sea.

A deep ocean current power plant is the power project in Gulf Stream belonging to Florida Atlantic University (refer to Kuroshio power plant development plan. Renewable and Sustainable Energy Reviews 14 (2010) 2655-2668). The nature of ocean currents in the two places is similar in the depth which is mostly more than hundreds of meters. However, the present invention uses different power plant structure and techniques.

### SUMMARY OF THE INVENTION

The first objective of the present invention is to provide a deep ocean current power plant, applied in sea with depth of more than 40 meters, which is able to convert kinetic energy generated from ocean current into electrical energy.

To achieve the above purpose, the deep ocean current power plant constructed in accordance with one embodiment of the present invention comprises a current generator group, a floating midway platform, a generator anchorage system, a midway platform anchorage system, and at least one power transmission-and-distribution cable.

The current generator group comprises turbines and generators which convert ocean flow into electrical energy. The functions of the current generator group are broadly divided into two types:

(1) Each of the current generator groups is powered individually, and then the groups are linked in series and/or in parallel to transmit power to the terrestrial network system via the power transmission-and-distribution cable.

(2) Each turbine of the current generator groups drives a hydraulic system in order to drive the generator.

The floating midway platform comprises the hollow-links which are mounted on a suitable connector to rotate, and then the floating midway platform is able to adapt the shape for the current interaction.

The generator anchorage system anchors the current generator group firmly above the floating midway platform.

The midway platform anchorage system anchors the floating midway platform to the seabed.

The power transmission-and-distribution cable transmits the power generated from the current generator group to an electrical power conversion equipment installed in the floating midway platform. After using frequency modulation, the power transmission-and-distribution cable is connected to a substation on the land. Thus, a pathway of the cable-lying route shuttles the floating midway platform and floats in sea instead of the seabed.

The second objective of the present invention is to provide a novel constructing procedure compared with traditional constructing procedure to reduce the cost and the difficulties associated with the construction, and then to increase the engineering reliability and product firmness.

To achieve the purpose mentioned above, the constructing procedure comprises steps of sea-throwing and cable-numbering; assembling a platform and anchoring undersea; anchoring a current generator group; and testing and correcting stability of overall structure.

In contrast with the prior art, following advantages and features of the invention are described.

First, a current generator group mounted undersea is different from the prior art of shallow-sea power plants which are mounted on sea surface. The structure is at the average water depth of tens meters. The real depth required for the construction of the present invention depends on the depth of water and the dispersion of the ocean current. Thus, the current generator group has the following advantages:
(1) According to the properly designed floating midway platform and the generator anchorage system in the invention, the structures is able to withstand typhoon with high waves of 10 m.
(2) Because the current generator group is placed hundreds of meters deep in the water all year round, the possibility for oxidation, corrosion, or biological attachment is less than those for the shallow-sea power plants.
(3) During the plant construction, the status of marine ecology is in great concern. The real fact is that the completed power plant of the present invention has little adverse affects on marine ecology.

Second, the floating midway platform has following advantages:
(1) It decreases effectively a required length of the generator anchorage system and promotes significantly an anchoring stability and reliability of the power plant of the present invention.
(2) Anchoring pathways of the floating midway platform considers the platform's direction via ocean current instead of anchoring to a specific position. The floating midway platform uses the sea-casting to anchor to the seabed, and thus this approach reduces the difficulty and the cost of the entire construction significantly because the anchor positions are chosen randomly. Furthermore, the floating midway platform not only reduces but avoids slumping or slipping of the seabed caused by earthquakes to affect the stability of the floating midway platform.
(3) Because the volume of the cables required for the present invention is large, all the cables are made of composite materials or polymer compounds so as to reduce the total weight of the cables. The cables possess advantages in weight, strength, and toughness. In the mean time, the cables have hairy-tail fibers at downstream reduce the high-frequency vibration on the cables caused by ocean current.
(4) The power transmission-and-distribution cable is mounted on the floating midway platform instead of touching the seabed, linked to another floating midway platform, and finally connected to a land substation. Consequently, the above steps reduce total length of cables, avoid scattering cables on the seabed, and eliminate broken cables caused by geological change after completing the power plant construction.
   Third, the advantages of the invention of the plant construction herein compared with conventional shallow-sea power plants' are:
(1) Sea-cast anchoring and cable-numbering: It does not require positioning in advance or constructing on a fixed position afterwards.
(2) Platform assembling and undersea anchoring: Most works are completed on sea surface or on land. Little works need to be done undersea. Therefore, the cost is relatively low and the construction is uncomplicated due to its simple structure.
(3) Current generator group anchoring: Same as stated in paragraph (2). Most of the works are completed on sea surface or on land. Little works need to be done undersea. Therefore, the cost is relatively low and the plant is easy to construct.
(4) Testing and correcting the stability of whole structure: It is a mature, standardized technology for testing and correcting the techniques and procedures. As a result, the cost is low and it is relatively simple to carry out. In summary, the stated constructing process will ease both difficulties and cost in the construction as well as improve the engineering reliability and finished work's stability.

As a whole, the above constructing procedure not only reduces the difficult of the construction, but also increases the reliability of the engineering and the stability of overall structure.

### BRIEF DESCRIPTION OF THE DRAWINGS

FIG. 1 is a side view of a better embodiment of a deep ocean current power plant in accordance with the present invention.

FIG. 2 is a block diagram of a better embodiment of a deep ocean current power plant in accordance with the present invention.

FIG. 3 is a schematic diagram of a better embodiment of a deep ocean current power plant in accordance with the present invention.

FIG. 4 is a flow chart of a better embodiment of a constructing procedure of the deep ocean current power plant in accordance with the present invention.

### DETAILED DESCRIPTION OF THE PRESENT INVENTION

Hereinafter, embodiments of the present invention will now be described in greater detail with reference to the accompanying drawings.

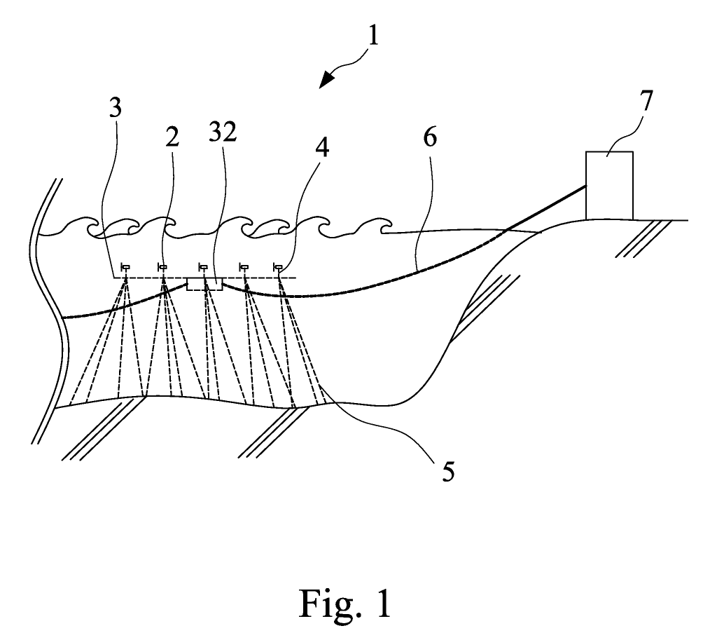

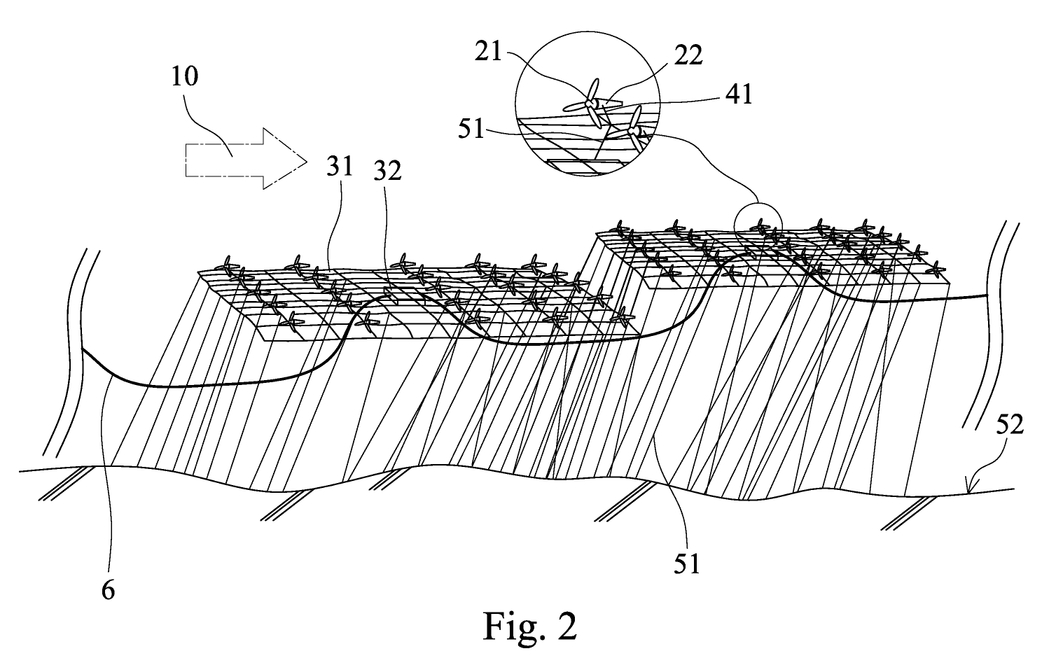

With reference to FIGS. 1 and 2, a better embodiment of a deep ocean current power plant (1) in accordance with the present invention is constructed in a sea with depth of more than 40 meters, such as the Kuroshio current in the eastern coast of Taiwan, in order to convert kinetic energy generated from ocean current into electrical energy. The deep ocean current power plant (1) comprises a current generator group (2), a floating midway platform (3), a generator anchorage system (4), a midway platform anchorage system (5), and at least one power transmission-and-distribution cable (6).

The current generator group (2), converting the ocean current into electrical energy, comprises at least one turbine (21) and one generator (22) respectively. The generator is driven by the turbine (21). The turbine (21) is either of a horizontal-axis or a vertical-axis turbine (21), and consists of a rotary machine with two to five blades. A casing for the turbine (21) needs to be built around the machine in order to increase energy conversion efficiency. Trunk parts of the turbine (21), such as the bearing and frame, which are more likely to be worn and function as the force body, shall be made of special alloys. Other components of the turbine (21) are made of composite materials. The generator (22) is driven by the turbine (21) or by a hydraulic system. The generator (22) is of low speed and high-torque, which leads to be of small radius and a long axis. The current generator group (2) will be long-term disposed in a deep-sea and, as a result, the possibility of oxidation corrosion is less than the ones in shallow waters. However, there are still possibilities having marine creatures clinging to the apparatus, which can be prevented by developing new eco-friendly coating materials. In addition, some metal components require processing with either electroplating or lubrication to prolong the lifespan of the metal components in the sea. The number of the current generator group (2) is better to be arranged in the range from 20 to 30.

The floating midway platform (3) comprises a plurality of hollow-links (31). An electrical power conversion equipment (32) is installed at the hollow-links (31). The floating midway platform (3) comprises the hollow links (31) mounted with a suitable connector (ex. ball-shaped connector). The floating midway platform (3) would be randomly deformed in low-frequency vibration by the external force, coming from the ocean current, the turbine's (21) tension, or the tension between the floating midway platform (3) and the seabed (52). The hollow-links (31) are preferably made of composite materials or plastic-steel materials. The floating midway platform (3) is arranged at a suitable depth level undersea, and the dimension of the platform is varied in accordance to the size of the power plant.

The generator anchorage system (4) anchors the current generator group (2) on and above the floating midway platform (3). The generator anchorage system (4) includes anchoring cables (41), which are made of polymer compounds or light-weight and of high-strength composite materials. Hairy-tail fibers can be affixed along the anchoring cables (41) at downstream to reduce the low frequency swing or the high-frequency vibration on the anchoring cables (41) caused by ocean current.

The midway platform anchorage system (5) anchors the floating midway platform (3) to a seabed (52). The midway platform anchorage system (5) comprises a plurality of submarine cables (51), which are made of polymer compounds or light-weight and of high-strength composite materials. Hairy-tail fibers can be affixed along the submarine cables (51) at downstream to reduce the low frequency swing or the high-frequency vibration on the submarine cables (51). Tens or hundreds of the submarine cables (51) are mounted on the seabed (52). It does not require identifying the anchoring positions and locations of the submarine cables beforehand. The directions to extend the submarine cables (51) must take account of the ocean current flow motion, which is the ocean current kinetic energy (10), and the floating midway platform (3) is able to eliminate possible significant displacement or any large-scale deformation under strong external forces.

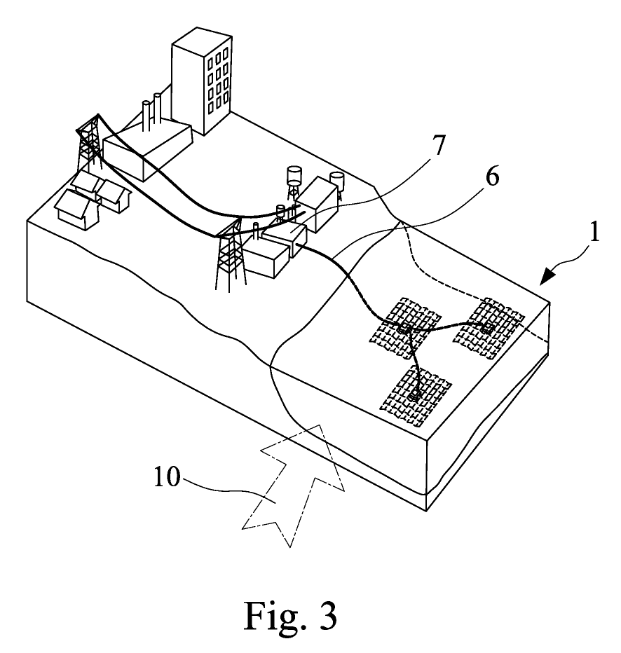

At least one power transmission-and-distribution cable (6) transfers power produced by the current generator group (2) to a set of electrical power conversion equipment (32) which is mounted on the floating midway platform (3). As shown in FIG. 3, after using frequency modulation, the power is transmitted to a terrestrial network system, such as a land substation (7). The power transmission-and-distribution cables (6) are linked in series and/or in parallel.

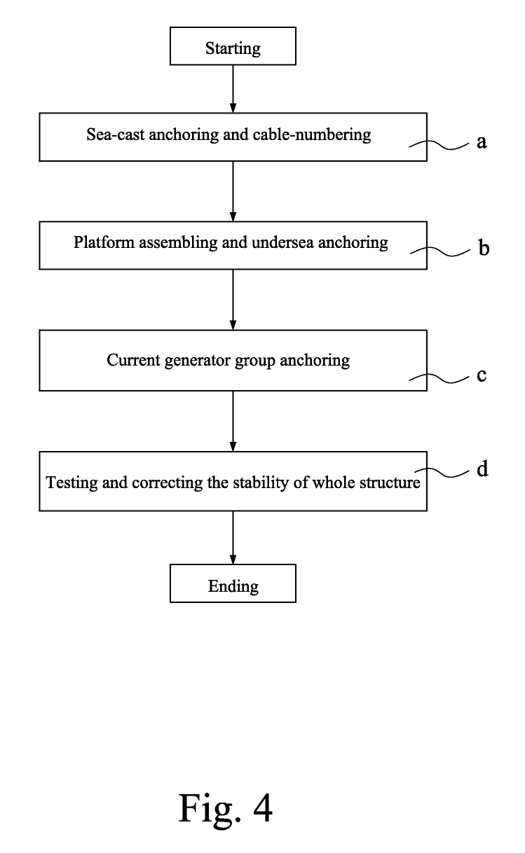

As shown in FIG. 4, a better embodiment of a constructing procedure of the deep ocean current power plant in accordance with the present invention comprises follow steps:
(a) Sea-cast anchoring and cable-numbering:

A midway platform anchorage system (5) comprises a plurality of submarine cables (51) which are numbered in advance. The submarine cables (51) are casted into sea and then are fixed on a seabed (52).
(b) Platform assembling and undersea anchoring:

A floating midway platform (3) comprises a plurality of hollow-links (31) which are assembled in advance. The floating midway platform (3) presents a balance between buoyancy and gravity via injecting water into the hollow-links (31). The numbered submarine cables (51) are fixed to the floating midway platform (3), and then are regulated to let the floating midway platform (3) sink to a suitable depth level undersea. Subsequently, the water in the hollow-links (31) is removed in order to produce buoyancy. Thus, the floating midway platform (3) floats stably in the sea because of the buoyancy and a force of the submarine cables (51).
(c) Current generator group anchoring:

A generator anchorage system (4) comprises a plurality of anchoring cables (41). A current generator group (2) anchors to the floating midway platform (3) via the anchoring cables (41). The current generator group (2) presents a balance between buoyancy and gravity in order to let the current generator group (2) float stably in the sea.
(d) Testing and correcting the stability of whole structure:

Finally, it is to adjust length between the anchoring cables (41) of the generator anchorage system (4) and the submarine cables (51) of the midway platform anchorage system (5), and to adjust strength of buoyancy between the floating midway platform (3) and the current generator group (2). Thus, above steps let the floating midway platform (3) and the current generator group (2) set and float stably on the ocean current, and then continue producing power.

While various embodiments are discussed herein, it will be understood that they are not intended to limit to these embodiments. On the contrary, the presented embodiments are intended to cover alternatives, modifications and equivalents, which may be included within the spirit and scope of the various embodiments. Furthermore, in this Description of Embodiments, numerous specific details are set forth in order to provide a thorough understanding of embodiments of the present subject matter. However, embodiments may be practiced without these specific details. In other instances, well known steps, procedures, components, and circuits have not been described in detail as not to unnecessarily obscure aspects of the described embodiments.

What is claimed is:

1. A deep ocean current power plant comprising:
a current generator group for converting kinetic energy generated from ocean current into electrical energy, wherein the current generator group comprises at least one turbine and at least one generator;
a floating midway platform comprising a plurality of hollow-links mounted on an electrical power conversion equipment;
a generator anchorage system anchoring the current generator group to the floating midway platform;
a midway platform anchorage system anchoring the floating midway platform to a seabed; and
at least one power transmission-and-distribution cable transmitting electrical energy which is generated from the current generator group to the electrical power conversion equipment, and connecting to a land substation.

2. The deep ocean current power plant of claim 1, wherein the turbine consists of horizontal-axis turbine.

3. The deep ocean current power plant of claim 1, wherein the turbine consists of vertical-axis turbine.

4. The deep ocean current power plant of claim 1, wherein the generator is driven by the turbine.

5. The deep ocean current power plant of claim 1, wherein the generator is driven by a hydraulic system which is produced by the turbine.

6. The deep ocean current power plant of claim 1, wherein the generator anchorage system comprises anchoring cables which are made of polymer compounds.

7. The deep ocean current power plant of claim 1, wherein the generator anchorage system comprises anchoring cables which are made of light-weight and high-strength composite materials.

8. The deep ocean current power plant of claim 1, wherein the midway platform anchorage system comprises submarine cables which are made of polymer compounds.

9. The deep ocean current power plant of claim 1, wherein the midway platform anchorage system comprises submarine cables which are made of light-weight and high-strength composite materials.

10. The deep ocean current power plant of claim 1, wherein the power transmission-and-distribution cables are linked in series and/or in parallel.

11. A constructing procedure of the deep ocean current power plant, comprising following steps:
numbering at least one submarine cable which is included in a midway platform anchorage system;
injecting water into a plurality of hollow-links which are included in a floating midway platform;
fixing the submarine cables to the floating midway platform;
anchoring a current generator group via at least one anchoring cable which is included in a generator anchorage system to the floating midway platform; and
setting the floating midway platform and the current generator group stably on the ocean current.

12. The constructing procedure of the deep ocean current power plant of claim 11, wherein the step of numbering at least one submarine cable which is included in a midway platform anchorage system further comprises steps of:
casting the submarine cables into the sea; and
fixing the submarine cables on a seabed.

13. The constructing procedure of the deep ocean current power plant of claim 11, wherein the step of injecting water into a plurality of hollow-links which are included in a floating midway platform further comprises steps of:
removing the water in the hollow-links; and
regulating the submarine cables to let the floating midway platform sink to a suitable depth level undersea.

14. The constructing procedure of the deep ocean current power plant of claim 11, wherein the step of setting the floating midway platform and the current generator group stably on the ocean current further comprises steps of:
adjusting a buoyancy between the floating midway platform and the current generator group; and
producing power.
